(19) United States
(12) Patent Application Publication
(10) Pub. No.: US 2026/0260686 A1
(43) Pub. Date: Sep. 3, 2026

(54) DYNAMIC RANDOM-ACCESS MEMORY (DRAM) ARCHITECTURE WITH MULTIPLE READ-WRITE MODES

(71) Applicant: SHENZHEN GOODIX TECHNOLOGY CO.,LTD., Shenzhen (CN)

(72) Inventor: XinHua YU, Shenzhen (CN)

(21) Appl. No.: 19/067,976

(22) Filed: Mar. 2, 2025

(51) Int. Cl. G11C 11/4096; G11C 11/4076; G11C 29/52

(52) U.S. Cl. CPC G11C 11/4096; G11C 11/4076; G11C 29/52

(57) ABSTRACT

A dynamic random-access memory (DRAM) architecture is described having dual-mode capabilities for improved memory access, such as by both central processing unit (CPU) and neural processing unit (NPU) applications. Embodiments provide asymmetrical transfer rates, providing higher bandwidth for read operations while maintaining conventional speeds for writes. For example, embodiments can include dual clock sources, advanced modulation techniques, and/or error correction coding to mitigate increased bit error rates due to increased read speeds in higher-transmission-speed (HTS) operating modes as compared to lower-transmission-speed (LTS) operating modes. Embodiments can support concurrent LTS and HTS operations within the same memory system, enhancing overall system performance, reducing power consumption, and helping to maintain data integrity without significant latency penalties.

### TECHNICAL FIELD

The present document relates to memory circuits, and, more particularly, to dynamic random-access memory (DRAM) circuit and architectures supporting symmetric and asymmetric read-write modes.

### BACKGROUND

Dynamic random-access memory (DRAM) is a ubiquitous component in modern computing systems, providing temporary data storage for processor operations. Traditional DRAM architectures are designed primarily to meet the needs of central processing units (CPUs), including providing low latency for both read and write operations. These designs tend to utilize symmetrical transfer rates, where the speed is used for reading data from and writing data to the memory. Such symmetry helps to provide general-purpose computing tasks with balanced performance between read and write operations. However, certain such design goals and optimizations of conventional DRAM architectures are not well-suited to many modern processor applications. For example, neural processing units (NPUs) tend to perform tasks involving a widely disproportionate frequency of read operations as compared to write operations.

### BRIEF SUMMARY

Embodiments herein include systems and methods for providing flexible read-write symmetry in dynamic random-access memory (DRAM) architectures. The DRAM can support symmetric read and write transfer rates for supporting operations such as those of a central processing unit (CPU) and asymmetric read and write transfer rates for supporting operations such as those of a neural processing unit (NPU). For example, different operating modes of the DRAM architecture can support different data rates and/or different bandwidths for read operations while maintaining a consistent data rate and bandwidth for write operations, thereby improving memory performance for read-intensive NPU applications without compromising the low-latency requirements of CPU operations. Some implementations include dual clock sources within the DRAM. Some implementations also include advanced modulation techniques and/or error correction coding to mitigate increased bit error rates due to increased read speeds in NPU operating modes. Embodiments can support concurrent CPU and NPU operations within the same memory system.

The drawings, the description and the claims below provide a more detailed description of the above, their implementations, and features of the disclosed technology.

### BRIEF DESCRIPTION OF THE DRAWINGS

The accompanying drawings, referred to herein and constituting a part hereof, illustrate embodiments of the disclosure. The drawings together with the description serve to explain the principles of the invention.

FIG. 1 shows an illustrative implementation of a multi-modal dynamic random-access memory (DRAM) architecture, according to embodiments described herein.

FIGS. 2A and 2B show a host memory controller 200 and a DRAM, respectively, of an illustrative implementation of a multi-modal DRAM architecture, according to some embodiments described herein.

FIG. 3 shows an alternative implementation of a host memory controller for a multi-modal DRAM architecture, according to embodiments described herein.

FIG. 4 shows a partial view of an alternative implementation of a DRAM architecture in which the memory clock controller in the host memory controller generates two clocks for two clock domains, according to embodiments described herein.

FIG. 5 shows a partial view of another alternative implementation of a DRAM architecture in which the memory clock controller in the host memory controller generates one clock for one clock domain, and a phase-lock loop (PLL) in the DRAM is used to generate another clock for another clock domain, according to embodiments described herein.

FIGS. 6A and 6B show a host memory controller and a DRAM, respectively, of an illustrative implementation of a multi-modal DRAM architecture, according to some embodiments described herein.

FIG. 7 shows a flow diagram of a method for multi-mode data transfer in a DRAM architecture, according to embodiments described herein.

In the appended figures, similar components and/or features can have the same reference label. Further, various components of the same type can be distinguished by following the reference label by a second label that distinguishes among the similar components. If only the first reference label is used in the specification, the description is applicable to any one of the similar components having the same first reference label irrespective of the second reference label.

### DETAILED DESCRIPTION

In the following description, numerous specific details are provided for a thorough understanding of the present invention. However, it should be appreciated by those of skill in the art that the present invention may be realized without one or more of these details. In other examples, features and techniques known in the art will not be described for purposes of brevity.

Traditional DRAM architectures are designed primarily to meet the needs of central processing units (CPUs). For example, support for general-purpose computing tasks can involve a balanced performance approach, such as by providing low latency for both read and write operations and symmetrical read and write data transfer rates. However, such a balanced approach may not be optimal for more specialized types of processors and/or processing applications. In the face of increasing demands for higher transmission speeds, the read and write data transfer rates may become asymmetric, and traditional DRAM architectures cannot meet such scenario requirements. For example, this is relevant in fields such as artificial intelligence(AI), machine learning(ML), image processing, and video encoding and decoding.

For example, neural processing units (NPUs) have emerged as specialized processors optimized for handling complex AI/ML algorithms, such as convolutional neural networks (CNNs) and transformers. Such algorithms are integral to tasks like image recognition and natural language processing. A notable characteristic of NPU workloads is the disproportionate frequency of read operations as compared to write operations. NPUs tend to access large volumes of data, including pre-trained model weights and input datasets, often relying on high data bandwidth for read operations. However, write operations largely involve storing outputs or intermediate computation results, which tend to occur less frequently.

The symmetrical transfer rates of conventional DRAM designs tend not to be optimized for NPU workloads. Conventional attempts to address NPU workloads typically focus on increasing transfer rates (i.e., both read and write data transfer rates), such as by enhancing serializer/deserializer (SerDes) input/output (I/O) transfer speeds. This can result in degraded signal quality, poor eye diagrams, higher bit error rates (BER), and/or other undesirable effects. Some conventional attempts additionally or alternatively lower the signal voltage swing to reduce power consumption, which can further exacerbate signal integrity issues, leading to increased BER and unreliable data transmission.

Embodiments described herein include DRAM architectures that can support asymmetrical transfer rates to address the specific needs of high-speed processing units, such as NPUs. Some embodiments of the DRAM architectures support flexible read-write symmetry by operating in selectable modes including at least a symmetric (e.g., CPU-tailored) mode and an asymmetric (e.g., NPU-tailored) mode. For example, the different modes can support different data rates for read operations (i.e., higher bandwidth for the HTS mode than for the LTS mode) while maintaining conventional rates for write operations, thereby optimizing memory performance for read-intensive (e.g., NPU) applications without compromising low-latency requirements for CPU operations. Implementations include the use of dual clock sources within the DRAM to support high-speed read operations through a dedicated high-frequency clock and lower (e.g., standard) read/write operations via a low-frequency clock.

Some embodiments described herein include advanced modulation techniques, such as pulse amplitude modulation with four levels (PAM4), to support high-speed read operations with increased data throughput without a proportional increase in clock rate or baud rate. For low-speed read and write operations, non-return-to-zero (NRZ) modulation can be used for reliable data transmission. To mitigate increased BER associated with higher-speed data transfers, error correction coding techniques can be used, such as by integrating forward error correction (FEC) codes into the data path. Some embodiments implement the error correction coding with the encoder in the DRAM and the decoder in a host processor. Other embodiments implement the error correction coding with both the encoder and the decoder in the host processor.

As described herein, embodiments support dynamic switching between one or more lower-transmission-speed (LTS) modes (e.g., a symmetric, LTS mode) and one or more higher-transmission-speed (HTS) modes (e.g., an asymmetric, HTS mode), controlled by commands from the host processor. For example, the DRAM can be switched burst-by-burst to handle data transfers in a manner optimized for each incoming burst. In some embodiments, the mode can be controlled by commands sent to the DRAM, allowing high-speed and low-speed read bursts to be transferred alternately. This capability can be useful, for example, when a CPU and an NPU are running simultaneously, enabling each processor to access memory in the mode best suited to its operational needs. Thus, a single memory system can be shared by, and concurrently optimized for, each of multiple processing pipelines.

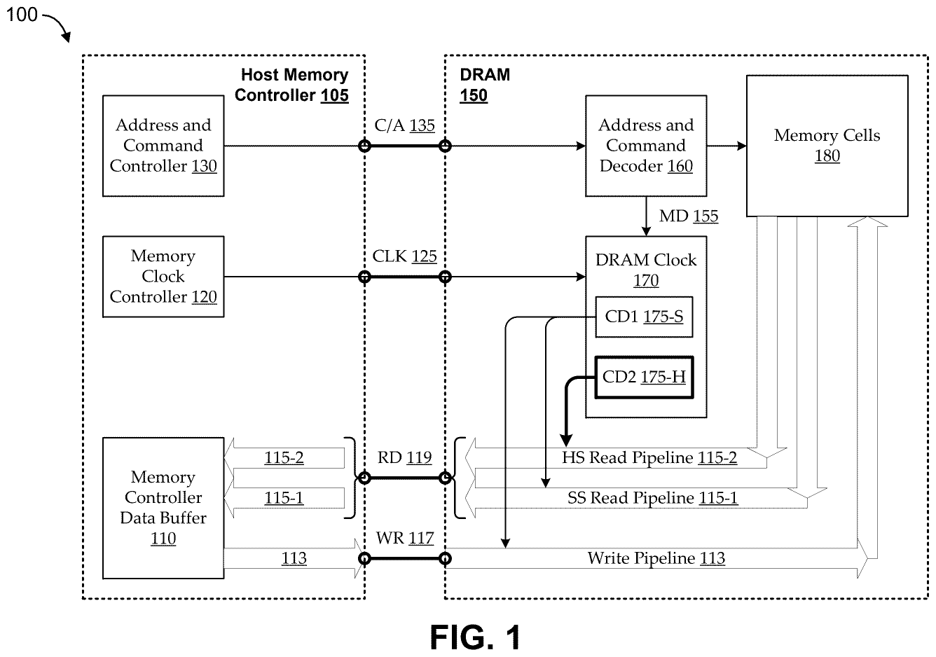

FIG. 1 shows an illustrative implementation of a multi-modal DRAM architecture 100, according to embodiments described herein. The DRAM architecture 100 encompasses the collaborative functioning of a host memory controller 105 and a DRAM 150. The architecture 100 is described in relation to three data transfer paths, or “pipelines”: a write pipeline 113 from the host memory controller 105 to the DRAM 150, a standard-speed (SS) read pipeline 115-1 from the DRAM 150 to the host memory controller 105 when configured in a LTS mode (i.e., for symmetric read-write data transfer), and a high-speed (HS) read pipeline 115-2 from the DRAM 150 to the host memory controller 105 when configured in an HTS mode (i.e., for asymmetric read-write data transfer).

The host memory controller 105 acts as the interface between one or more processors and the memory system. It manages the flow of data, commands, and addresses, orchestrating read and write operations with precise timing and control. For example, responsibilities of the host memory controller 105 include buffering data, performing error correction, and ensuring synchronization between the processor's demands and the memory's capabilities. As illustrated, the host memory controller 105 includes a memory controller data buffer 110, a memory clock controller 120, and an address and command controller 130.

The DRAM 150 serves as the storage component of the architecture 100, housing data in a structured array of memory cells 180 organized into banks, rows, and columns. It responds to the commands and addresses issued by the memory controller, executing the actual read and write operations to store or retrieve data. As illustrated, the DRAM 150 includes an address and command decoder 160 in communication with the address and command controller 130 of the host memory controller 105, a DRAM clock 170 in communication with the memory clock controller 120 of the host memory controller 105, and pipeline components (not explicitly shown) for facilitating read and write data transfers between the memory cells 180 and the memory controller data buffer 110 of the host memory controller 105.

The memory cells 180 are a type of volatile memory that stores each bit of data in a separate capacitor within an integrated circuit. These capacitors can hold a charge representing a binary ‘1’ or ‘0’, but they naturally discharge over time, leading to potential data loss. To prevent this, DRAM 150 requires periodic refreshing of each capacitor's charge, which is managed by a refresh controller. The DRAM 150 is organized into banks to facilitate parallel access operations. Each bank contains a grid-like structure of the memory cells 180 arranged in rows and columns. Row decoders and column decoders interpret address signals to access specific memory locations. When a memory operation is initiated, the appropriate row is activated by the row decoder, enabling access to all columns within that row simultaneously. This activated row is transferred to sense amplifiers, which detect and amplify the small voltage differentials representing the stored data.

All of the data transfer paths rely on precise timing and synchronization, which is facilitated by the memory clock controller 120 and the DRAM clock 170. The memory clock controller 120 generates a master clock signal (CLK) 125. This can involve using a phase-locked loop (PLL) to multiply a reference clock frequency. In some embodiments, CLK 125 is a high-frequency clock signal for high-speed data transmission, and any other clock signals are divided down versions of that clock signal. Other embodiments can use CLK 125 in any suitable manner to generate the clock signals used by data transfer operations. CLK 125 is passed to the DRAM clock 170 in the DRAM 150.

Within the DRAM clock 170, CLK 125 is used to generate a standard-speed clock domain (CD1) 175-S and a high-speed clock domain (CD2) 175-H. In one embodiment, CD1 175-S operates at 1600 Megahertz (MHz), and CD2 175-H operates at 3200 MHz. For example, CD2 175-H is generated directly from CLK 125, and CD1 175-S is generated by dividing CLK 125 (e.g., by 2, or another suitable integer). Some embodiments include a LTS mode that uses symmetric read-write data transfer rates and an HTS mode that uses asymmetric read-write data transfer rates. In such embodiments, timing of both the write pipeline 113 and the SS read pipeline 115-1 are based on CD1 175-S, and timing of the HS read pipeline 115-2 is based on CD2 175-H. Although only two clock domains 175 are shown, other implementations can generate additional and/or different clock domains 175. For example, instead of having a symmetric mode and an asymmetric mode, embodiments can be designed for multiple different asymmetric modes for which more than two clock domains 175 are used to provide different read-write data rate ratios.

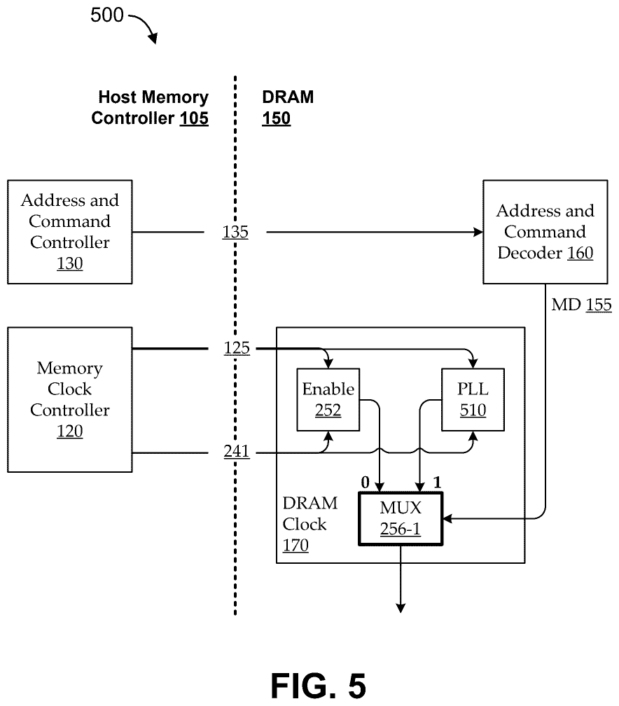

In some embodiments, two clock domains are generated using a PLL with adjustable input and output dividers within the DRAM 150 (e.g., in FIG. 5 below). The high-speed clock frequency can be set to M/N times the input clock frequency, where M is the post-divider and N is the input divider of the PLL (e.g., both M and N are integers). This configuration offers more flexibility for the high-speed data rate, allowing the external clock input to run at a lower speed and potentially reducing power consumption.

A write data transfer can begin with a set of write commands and associated addresses being issued by the address and command controller 130 and sent as C/A data 135 to the address and command decoder 160 in the DRAM 150. The C/A data 135 are interpreted by the address and command decoder 160 to identify the address information for the memory cells 180 in which data is to be written. The C/A data 135 can also indicate that a write is being performed and can cause the address and command decoder 160 to set a mode select (MD) signal 155 to direct use of CD1 175-S for clocking write operations. Concurrently, write data 117 is passed from the memory controller data buffer 110 through components of the write pipeline 113 (including from the host memory controller 105 to the DRAM 150, and the data is written to the appropriate memory cells 180.

A standard-speed read data transfer can begin with a set of read commands and associated addresses being issued by the address and command controller 130 and sent as C/A data 135 to the address and command decoder 160 in the DRAM 150. The C/A data 135 are interpreted by the address and command decoder 160 to identify the address information for the memory cells 180 from which data is to be read. The C/A data 135 also indicates that a standard-speed read is being performed and causes the address and command decoder 160 to set MD 155 to direct use of CD1 175-S for clocking read operations. The data from the designated memory cells 180 is read out to the SS read pipeline 115-1 through which it is passed (including from the DRAM 150 to the host memory controller 105) as read data 119 to the memory controller data buffer 110.

A high-speed read data transfer can begin with a set of read commands and associated addresses being issued by the address and command controller 130 and sent as C/A data 135 to the address and command decoder 160 in the DRAM 150. The C/A data 135 are interpreted by the address and command decoder 160 to identify the address information for the memory cells 180 from which data is to be read. The C/A data 135 also indicates that a high-speed read is being performed and causes the address and command decoder 160 to set MD 155 to direct use of CD2 175-H for clocking read operations. The data from the designated memory cells 180 is read out to the HS read pipeline 115-2 through which it is passed (including from the DRAM 150 to the host memory controller 105) as read data 119 to the memory controller data buffer 110.

In some embodiments, power consumption in high-speed modes is further reduced by lowering the voltage swing of the signaling. Although lowering the voltage swing reduces power consumption, it can result in an increased bit error rate (BER) due to a lower signal-to-noise ratio (SNR). This issue can be mitigated by employing forward error correction (FEC) codes to correct errors induced by the higher BER, ensuring reliable data transmission even with reduced voltage levels.

Embodiments can continuously provide multiple clock domains 175 to the DRAM 150 and can toggle between the clock domains 175 based on a mode select signal 155 generated based on C/A data 135 being sent by the address and command controller 130 of the host memory controller 105. For example, embodiments can quickly and seamlessly toggle between high-speed and standard-speed clock domains 175 by simply toggling the level of a control signal. This facilitates dynamic DRAM 150 mode switching (e.g., between a LTS and an HTS mode) on a burst-by-burst basis.

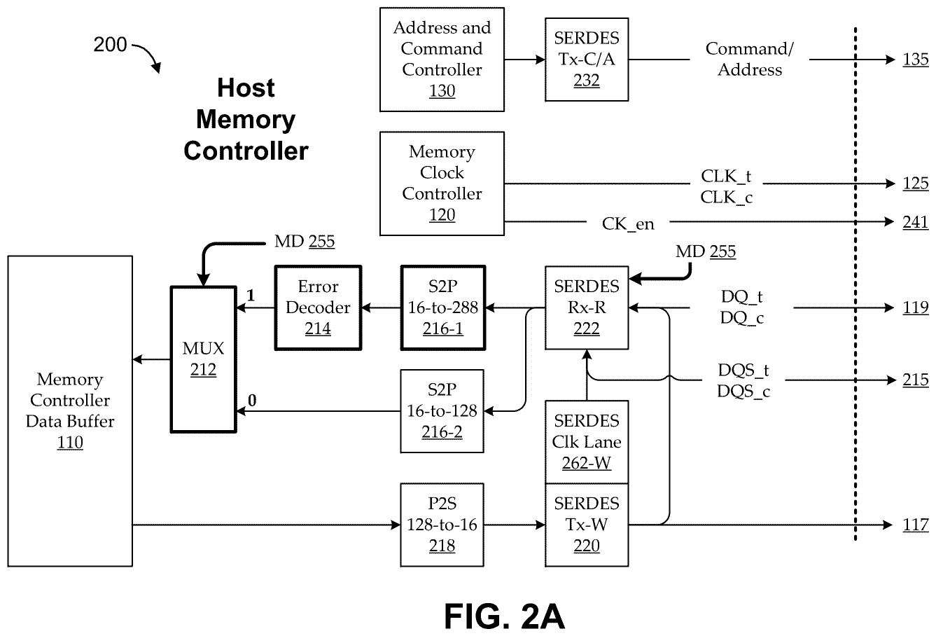

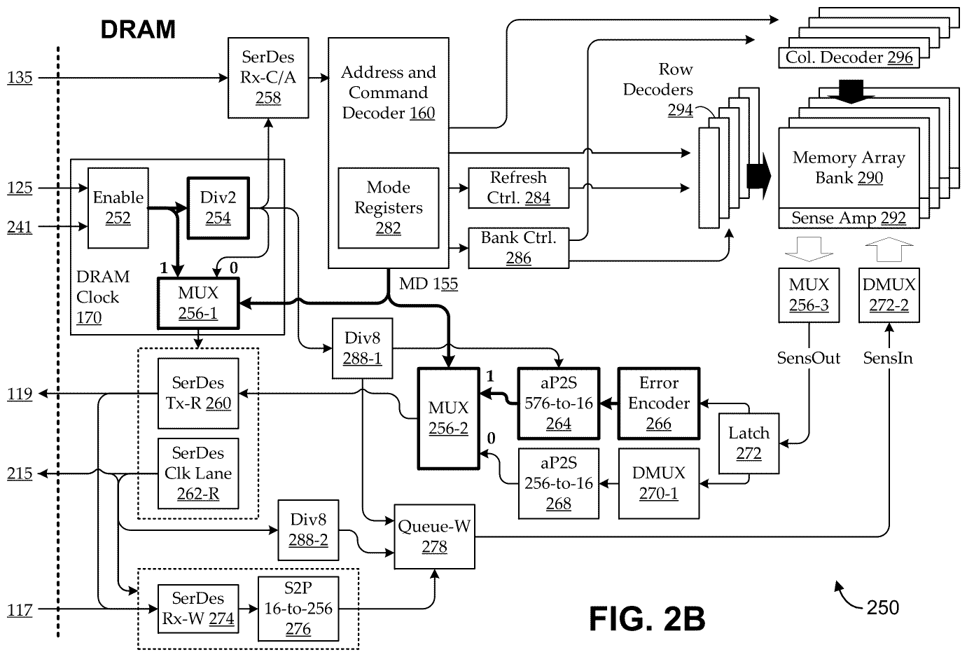

FIGS. 2A and 2B show a host memory controller 200 and a dynamic random-access memory (DRAM) 250, respectively, of an illustrative implementation of a multi-modal DRAM architecture, according to some embodiments described herein. The DRAM architecture of FIGS. 2A and 2B can be an implementation of the DRAM architecture 100 of FIG. 1, such that host memory controller 200 can be an implementation of host memory controller 105, and DRAM 250 can be an implementation of DRAM 150. The architecture of FIGS. 2A and 2B is described in relation to three data transfer paths: a write path from the host memory controller 200 to the DRAM 250, a read path from the DRAM 250 to the host memory controller 200 when configured in a LTS mode (i.e., for symmetric read-write data transfer), and the read path when configured in an HTS mode (i.e., for asymmetric read-write data transfer). These data transfer paths correspond to the write pipeline 113, SS read pipeline 115-1, and HS read pipeline 115-2 of FIG. 1, respectively. FIGS. 2A and 2B are described in parallel to provide a more holistic view of the DRAM architecture.

Turning first to the write data transfer path from the host memory controller 200 to the DRAM 250, data transmission begins at the host memory controller 200. Within the host memory controller 200, the memory controller data buffer 110 temporarily stores the write data. The memory controller data buffer 110 aligns the data with the host memory controller's timing, accommodating discrepancies between the processor's data output rates and the memory subsystem's capacity to receive data. It ensures a smooth and continuous flow of write data to the DRAM 250. The buffered data is serialized by a parallel-to-serial (P2S) converter 218 in communication with a SerDes transmitter (Tx) for write data (“SerDes Tx-W”) 220. In the illustrated implementation, the P2S converter 218 and the SerDes Tx-W 220 converts 128-bit parallel write data 205 into 16-bit serial streams suitable for high-speed transmission over the memory interface as serialized write data streams 117. Serialization reduces the number of physical data lines required, minimizing complexity and cost while maintaining high data transfer rates.

Concurrently, an address and command controller 130 handles the serialization of command and address signals. This controller converts parallel command and address data into a serialized command/address stream (i.e., C/A data 135), synchronizing it with the serialized write data streams 117. Precise timing and alignment ensure that commands and addresses correspond correctly to the associated data during transmission. The serialized write data streams 117 and serialized command/address stream 135 are sent over a physical medium to the DRAM 250.

Turning to FIG. 2B, within the DRAM 250, the SerDes receiver for write data (SerDes Rx-W) 274 receives the serialized write data streams 117. A serial-to-parallel (S2P) converter 276 performs a serial-to-parallel conversion. For example, the 16-bit serial streams are transformed back into 256-bit parallel data suitable for internal DRAM 250 processing. The receiver is designed to accurately recover the data despite any distortions or noise introduced during transmission. The deserialized write data is temporarily stored in an asynchronous write FIFO buffer (Queue-W) 278. Queue-W 278 helps to manage any timing differences between the external data arrival and the internal DRAM 250 processing speeds. Further, Queue-W 278 can help to ensure data integrity by holding the data until the DRAM 250 is ready to execute the write operation.

Concurrently, a SerDes receiver for command and address (SerDes Rx-C/A) 258 within the DRAM 250 deserializes the incoming serialized command/address stream 135. By converting these signals back to parallel form, the DRAM 250 can interpret and execute corresponding operations, such as activating specific rows and columns for data storage. As described with reference to FIG. 1, the DRAM 250 includes memory cells 180 for storing data. The memory cells are arranged as rows and columns of cells in memory bank arrays 290.

The deserialized command/address stream is passed to an address and command decoder 160 that interprets the received commands and addresses, facilitating accurate mapping to specific memory banks, rows, and columns. The address and command decoder 160 interprets commands like write, read, and refresh, ensuring they are executed correctly and efficiently. As illustrated, the address and command decoder 160 includes mode registers 282. Embodiments of the address and command decoder 160 output several signals for controlling row decoders 294 and column decoders 296, and also for directing a refresh controller 284 and a bank controller 286, as needed.

Within a selected memory bank 290, the row decoders 294 activate a targeted row for writing by decoding the row address and enabling the corresponding wordline. The column decoder 296 selects specific columns for the write operation, allowing precise placement of data within the memory array bank 290. This combination of row and column selection enables access to any memory cell within the array. The data can then be written into the DRAM's memory array bank 290. Sense amplifiers 292 associated with each memory cell facilitate the writing process by detecting and amplifying the small voltage levels that represent stored bits. During a write operation, the sense amplifiers help establish the necessary charge in the memory cells' capacitors, effectively storing the new data. As illustrated, write data from Queue-W 278 can be passed through a demultiplexer 272-2 and written to the appropriate memory cells.

Turning to the standard-speed read path (corresponding to the SS read pipeline 115-1 of FIG. 1), such as for a LTS mode (symmetric read-write), a corresponding symmetric read process can begin with the address and command decoder 160 in the DRAM 250 receiving a symmetric read command (as part of the C/A data 135 from the address and command controller 130). The address and command decoder 160 identifies the specific memory bank 290, row, and column addresses from which to retrieve the data. Additionally, the read command directs the address and command decoder 160 to output a mode control signal (MD) 155. In the illustrated implementation, mode control signal 155 controls multiplexers, MUX 256-1 and MUX 256-2, to be in either the LTS mode or the HTS mode for the read operation. The illustrated implementation associates input ‘0’ of multiplexers with the LTS read mode.

The bank control logic 286 activates the appropriate memory bank 290, coordinating with the row decoders 294 to enable the designated wordline corresponding to the requested row. The column decoder 296 selects the relevant columns, allowing access to the exact memory cells containing the requested data. The stored data is sensed by the sense amplifiers 292, which detect the minute electrical charges in the DRAM cells representing binary data. These amplifiers read the charge levels and convert them into standard voltage levels suitable for digital processing. The sensitivity and accuracy of the sense amplifiers are crucial for reliable data recovery. The read data can be multiplexed by MUX 256-3 onto a sense output (SensOut) line.

The amplified data is captured by the data latch 272, which temporarily holds the data to stabilize it before further processing. The data latch 272 prevents data corruption that could occur due to timing variations or electrical noise, ensuring that only valid data proceeds through the read path. The data can be routed through a demultiplexer (DMUX) 270-1 and then to an asynchronous P2S (aP2s) converter 268 (e.g., a first-in-first-out (FIFO), 256-to-16 converter). The aP2S converter 268 can also effectively move the data from a 1/16 clock domain to a ½ clock domain. As noted above, the mode select signal 155 directs MUX 256-2 to select the ‘0’ input, which is coupled with the aP2S converter 268, thereby passing through the synchronized, serialized read data to a SerDes transmitter for read data (SerDes TX-R) 260 within the DRAM 250.

As described herein, the LTS mode transfers the serialized read data at a lower data rate. At the lower data rate, the data can be transferred using a lower order modulation scheme, lower clock speed, etc. For example, the SerDes TX-R 260 can operate using non-return-to-zero (NRZ) modulation, which utilizes two voltage levels to represent binary data. NRZ modulation is robust and less susceptible to signal degradation, making it suitable for standard-speed data transmission. The serialized data from the SerDes TX-R 260 is transmitted back as read data 119 (DQ) to the host memory controller 200 over data lines. The implementation assumes differential signaling, so that each signal (e.g., DQ) is shown as a true and a complement of the signal (e.g., DQ_t and DQ_c, respectively). Alternatively, single-ended signaling can be used.

Turning back to FIG. 2A, upon reaching the host memory controller 200, the data is received by a SerDes receiver for read data (SerDes Rx-R) 222. The SerDes Rx-R 222 deserializes the incoming serial streams back into a parallel format suitable for processing by a downstream controller or processor. As illustrated, in the LTS mode, the SerDes Rx-R 222 operates with a S2P converter 216-2. For example, the SerDes Rx-R 222 and the S2P converter 216-2 can convert 16-bit serialized streams into 128-bit parallel streams. A multiplexer (MUX) 212 is set by the mode select signal 155 to pass the parallel streams from the S2P converter 216-2 to the memory controller data buffer 110.

Turning to the high-speed read path (corresponding to the HS read pipeline 115-2 of FIG. 1), such as for an HTS mode (asymmetric read-write), a corresponding asymmetric read process can begin with the address and command decoder 160 in the DRAM 250 receiving an asymmetric read command (as part of the C/A data 135 from the address and command controller 130). The address and command decoder 160 identifies the specific memory bank 290, row, and column addresses from which to retrieve the data. Additionally, the read command directs the address and command decoder 160 to output an appropriate value for MD 155. In this case, input ‘1’ of multiplexers are activated by the mode control signal 155 to activate the HTS read mode.

The bank control logic 286 activates the appropriate memory bank 290, coordinating with the row decoders 294 to enable the designated wordline corresponding to the requested row. The column decoder 296 selects the relevant columns, allowing access to the exact memory cells containing the requested data. The stored data is sensed by the sense amplifiers 292, which detect the minute electrical charges in the DRAM cells representing binary data. These amplifiers read the charge levels and convert them into standard voltage levels suitable for digital processing. The sensitivity and accuracy of the sense amplifiers are crucial for reliable data recovery. The read data can be multiplexed by MUX 256-3 onto a sense output (SensOut) line.

The amplified data is captured by the data latch 272, which temporarily holds the data to stabilize it before further processing. In the asymmetric read data path, the latched data is passed to an error encoder 266. In the illustrated implementation, the error encoder 266 applies a 64/8 single error correction double error detection (SECDED) code (e.g., a Hamming code) to the data, adding redundancy bits that allow for error detection and correction. For example, the DRAM 250 can transmit packets consisting of 512 bits of data combined with 64 bits of redundancy, forming a packet that includes eight blocks of 64/8 SECDED Hamming code. Using small packet sizes in this configuration allows for flexible utilization of DRAM space and efficient error correction processing. Incorporating forward error correction (FEC) enhances data reliability by enabling the correction of single-bit errors without the need for retransmission.

The encoded data is sent to an asynchronous P2S (aP2s) converter 264 (e.g., a first-in-first-out (FIFO), 576-to-16 bit converter). The aP2S converter 264 can also effectively move the data from a 1/16 clock domain to a full-speed (i.e., 2×) clock domain. In the illustrated embodiments, the symmetric read path serializes 256-bit read data bursts into 16-bit serialized streams at a half-speed clock domain (e.g., corresponding to CD1 175-S), while the asymmetric read path serializes 576-bit read data bursts into 16-bit serialized streams at a full-speed clock domain (e.g., corresponding to CD2 175-H). The mode select signal 155 directs MUX 256-2 to select the ‘1’ input, which is coupled with the aP2S converter 264, thereby passing through the synchronized, serialized high-speed read data to the SerDes TX-R 260.

As described herein, the HTS mode transfers read data at a higher data rate. At the higher data rate, the data can be transferred using a higher order modulation scheme, higher clock speed, etc. For example, the SerDes TX-R 260 is designed to support operation at this higher frequency and to utilize higher-order modulation schemes, such as pulse amplitude modulation with four levels (PAM4) for data transmission. PAM4 modulation increases the data rate by transmitting two bits per symbol through four distinct voltage levels. This effectively doubles the data throughput without increasing the symbol rate. Further, the SerDes TX-R 260 is designed to handle a wider data word to support appropriate serial streams for transmission.

The serialized high-speed data signal (also shown as read data 119, or DQ) is transmitted over the same physical data lines as in the lower-speed case. Turning back to FIG. 2A, upon reaching the host memory controller 200, the data is received by the SerDes Rx-R 222. The SerDes Rx-R 222 deserializes the incoming serial streams back into a parallel format suitable for processing by a downstream controller or processor. For example, in the HTS mode, the SerDes Rx-R 222 is configured to handle higher-order demodulation (e.g., PAM4) at higher data rates.

As illustrated, the SerDes Rx-R 222 operates with a S2P converter 216-1. For example, the SerDes Rx-R 222 and the S2P converter 216-2 can convert 16-bit serialized streams into 288-bit parallel streams. The parallel read data streams include error coding (e.g., redundancy) bits from the error encoder 266. The data is passed through an error decoder 214 in the host memory controller 200, which processes the received data and uses the error coding bits to correct any errors introduced during transmission. MUX 212 is set by the mode select signal 255 to pass the corrected, high-bandwidth read data from the error decoder 214 to the memory controller data buffer 110.

As described with reference to FIG. 1, the data transfer paths rely on precise timing and synchronization. For example, deserialization tasks rely on accurate timing recovery for accurate sample and symbol timing. As illustrated, the host memory controller 200 includes a memory clock controller 120. The illustrated embodiment assumes that the memory clock controller 120 generates a high-frequency clock signal for high-speed data transmission and outputs a corresponding clock (CLK) signal 125 (e.g., differentially as CLK_t and CLK_c). The memory clock controller 120 can also output a clock enable signal (CK_en) 241. Those signals are passed to a clock enable block 252 in the DRAM clock 170 block of DRAM 250, which effectively outputs a full-speed (high-speed) DRAM clock (e.g., corresponding to CD2 175-H).

In the illustrated embodiment, the full-speed DRAM clock (e.g., CD2 175-H) is used for asymmetric read data transfer operations, and a half-speed DRAM clock (e.g., CD1 175-S, generated by passing the full-speed DRAM clock through a divide-by-2 (DIV2) block 254) is used for symmetric read and write data transfer operations. Further, timing for the SerDes Rx-C/A 258 is based on the half-speed DRAM clock. As illustrated, MUX 256-1 selects between the full-speed and half-speed DRAM clocks based on the mode select signal 155, so that timing of the SerDes TX-R 260 is based on the full-speed DRAM clock for asymmetric read and on the half-speed DRAM clock for symmetric read operation.

A SerDes clock data lane 262-R generates data strobe (DQS) signals 215 for read (e.g., differentially as DQS_t and DQS_c). A corresponding SerDes clock data lane 262-W can be implemented in the host memory controller 200 to generate DQS for write operations. The DQS signals help with SerDes synchronization across the read and write paths and between the DRAM 250 and host memory controller 200. For example, the half-speed DRAM clock is divided again by eight via a Div 8 block 288-1 to produce a 1/16 clock domain. Timing of the write queue (Queue-W 278) and the read queues (aP2S converter 264 and aP2S converter 268) are based on the 1/16 clock domain, while the Queue-W 278 is also fed the DQS signals 215 divided by 8 (by Div8 block 288-2). At the host memory controller 200 side, timing of the SerDes Rx-R 222 is also synchronized by the DQS signals 215 to help ensure that the host memory controller 200 accurately samples the incoming read data with correct timing.

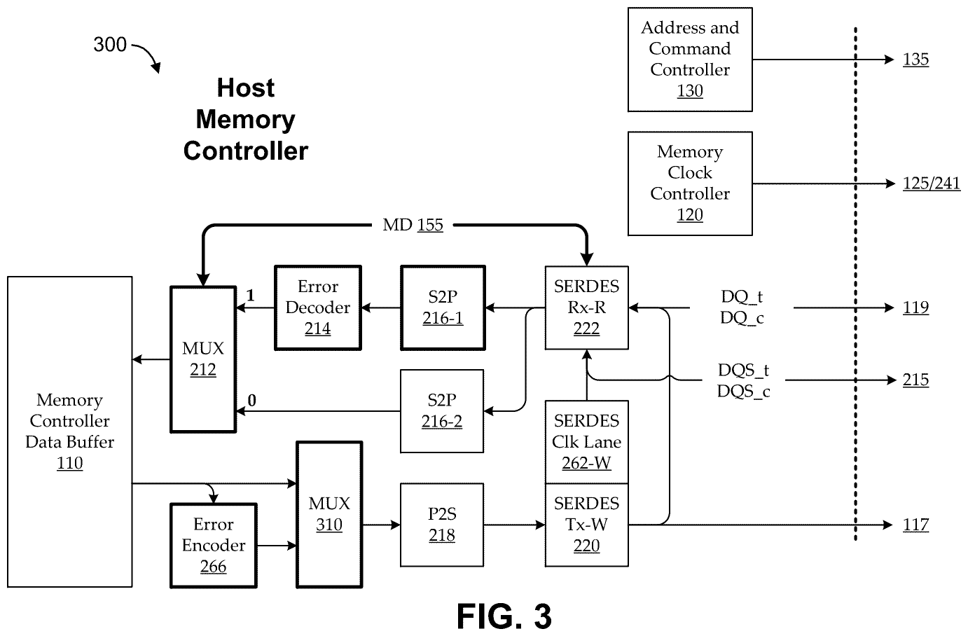

FIG. 3 shows an alternative implementation of a host memory controller 300 for a multi-modal DRAM architecture, according to embodiments described herein. The host memory controller 300 can be an implementation of the host memory controller 105 of FIG. 1 and is configured to interface with a DRAM, such as the DRAM 150 of FIG. 1. In the implementation of FIGS. 2A and 2B, the HS read pipeline 115-2 includes an error encoder 266 in the DRAM 250 and an error decoder 214 in the host memory controller 200. The implementation of FIG. 3 implements both the error encoder 266 and the error decoder 214 in the host memory controller 300.

As illustrated, the host memory controller 300 includes an additional MUX 310 for selectively feeding the write pipeline 113 with the write data alone or with the write data and error coding (e.g., redundant) bits. For example, the host memory controller 300 can use the MUX 310 to select between transmitting raw write data or write data augmented with error correction code (ECC) redundancy. The error encoder 266 processes the write data by applying an ECC. For example, a Hamming code, or other ECC scheme is used to generate redundancy bits for error detection and correction during data retrieval. In some embodiments, the error encoder 266 transmits one ECC burst having a burst length of 16 (BL16) for every eight data bursts (also BL16). The encoding process can begin after 256 bytes have been accumulated from the data buffer. For example, the initial data is transmitted without ECC encoding, so that lower latency can be provided on smaller data transfers, while subsequent data transmissions include periodic ECC bursts to enhance error correction capabilities for larger data blocks.

By handling all error encoding/decoding functionality in the host memory controller 300, the DRAM 150 can be implemented without any error encoding/decoding functionality (i.e., there is no error encoder 266 in the DRAM 150). In this embodiment, while the circuits in the DRAM 150 may be simpler, some DRAM space is used for redundancy. For example, the system can transfer eight data bursts of burst length 16 (BL16) with one ECC burst of BL 16, resulting in packets of 2048 bits of data and 256 bits of ECC. This forms a large packet containing 64 blocks of 64/8 SECDED Hamming code, which, while increasing DRAM space usage for redundancy, can simplify the DRAM circuitry and leverages the host controller's processing capabilities for error correction. In another implementation, the bit-width of DQ can be increased to transfer the redundancies. For example, 16-bit data is transferred by eight DQ lanes, and 2-bit redundancy is transferred by 2 DQ lanes.

On the read path, the error decoder 214 can be implemented in the same described with reference to FIG. 2A above. The error decoder 214 is responsible for processing incoming data from the DRAM 150, detecting, and correcting any errors that may have occurred during storage or transmission. In some embodiments, the error decoder 214 is configured to expect one BL16 ECC burst for every eight BL16 data bursts, mirroring the transmission pattern established during the write process. Decoding can begin after receiving 288 bytes, which corresponds to nine BL 16 bursts of 16 bits each (9×16×16 bits). This delay can help to ensure that the error decoder 214 aligns correctly with the incoming ECC bursts relative to the data bursts, facilitating accurate error detection and correction once sufficient data has been received.

The absence of an internal error encoder can simplify the design of the DRAM 150. The DRAM 150 can simply store and retrieve data as is, whether it includes ECC parity bits or not. During write operations, the DRAM 150 can agnostically receive either the raw write data or the write data with appended ECC bits, depending on the selection made by the MUX 310 in the host memory controller 300. Use of the MUX 310 can further provide operational flexibility in the host memory controller 300. For example, the MUX 310 can be directed to more frequently apply ECC to the write data in cases where data integrity is more critical than latency; and the MUX 310 can be directed to less frequently apply ECC to the write data in cases where latency is more critical than data integrity, and/or where data transfer is less error-prone.

Although implementations are described as transmitting one ECC burst for every eight data bursts, other implementations can use different ratios of ECC to data bursts. Further, although implementations are described as beginning encoding only after 256 bytes and/or beginning decoding only after 288 bytes, other implementations can begin encoding and/or decoding processes either immediately, or after any other suitable number of bytes.

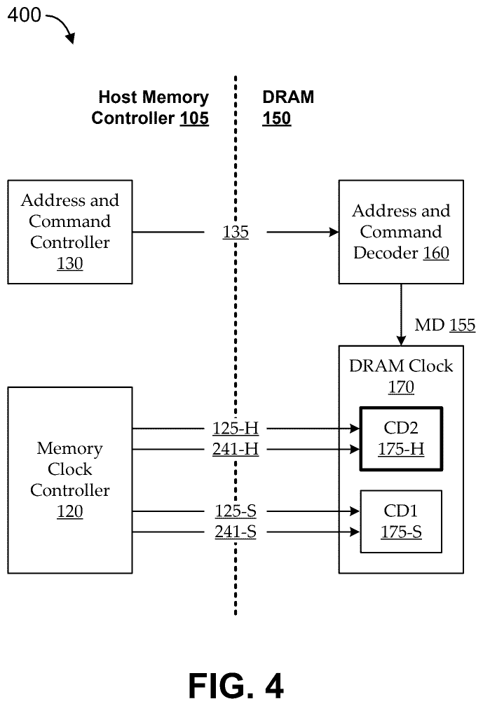

FIG. 4 shows a partial view of an alternative implementation of a DRAM architecture 400 in which the memory clock controller 120 in the host memory controller 105 generates two clocks for two clock domains, according to embodiments described herein. In this configuration, the memory clock controller 120 produces both a high-speed clock signal (CLK_H) 125-H and a standard-speed clock signal (CLK_S) 125-S. Generating both clock signals directly from the host memory controller 105 can allow for more flexibility in setting the data rates (e.g., the high-speed data rate) and can simplify clock management within the DRAM. The memory clock controller 120 can also generate a corresponding two clock enable signals, CK_en_H 241-H and CK_en_S 241-S, which are sent from the host memory controller 105 to the DRAM 150.

As described herein, the high-speed clock signal CLK_H 125-H can be used to synchronize high-speed read operations in the DRAM 150, facilitating the HTS mode where read operations involve higher bandwidth. Conversely, the standard-speed clock signal CLK_S 125-S can be used for both write operations and for standard-speed read operations, aligning with the LTS mode that uses symmetrical read-write performance.

Within the DRAM 150, the two clock signals are received and managed to create two separate clock domains: CD2 175-H for high-speed operations and CD1 175-S for standard-speed operations. The mode select signal 155, generated based on commands from the address and command controller 130, directs the DRAM 150 to switch between these two clock domains depending on the operation mode (e.g., whether the present burst is using the write pipeline 113, the SS read pipeline 115-1, or the HS read pipeline 115-2).

FIG. 5 shows a partial view of another alternative implementation of a DRAM architecture 500 in which the memory clock controller 120 in the host memory controller 105 generates one clock for one clock domain, and a phase-lock loop (PLL) in the DRAM 150 is used to generate another clock for another clock domain, according to embodiments described herein. In this configuration, the memory clock controller 120 produces a single clock signal CLK 125, along with a clock enable signal CK_en 241, which are both sent to the DRAM 150. Within the DRAM 150, the received clock signal is managed by the DRAM clock module 170, which includes a PLL 510. The PLL 510 generates a high-speed clock signal by multiplying the frequency of the received clock signal, creating the second clock domain needed for high-speed read operations. The original clock signal maintains the standard clock domain for write operations and standard-speed read operations.

For example, the PLL 510 can be configured with adjustable input and output dividers. In such implementations, the high-speed clock frequency can be M/N times the input clock frequency, where M is the post-divider and N is the input divider of the PLL. This offers more flexibility for the high-speed data rate and allows the external clock input to run at a lower speed, potentially reducing power consumption.

Similar to FIG. 2B, a multiplexer (MUX) 256-1 within the DRAM clock 170 selects between the standard clock domain (CD1 175-S) and the high-speed clock domain (CD2 175-H) based on the mode select signal 155, which is determined by commands from the address and command controller 130. This allows the DRAM 150 to dynamically switch between modes, such as between LTS and HTS modes, by internally generating the high-frequency clock through the PLL 510.

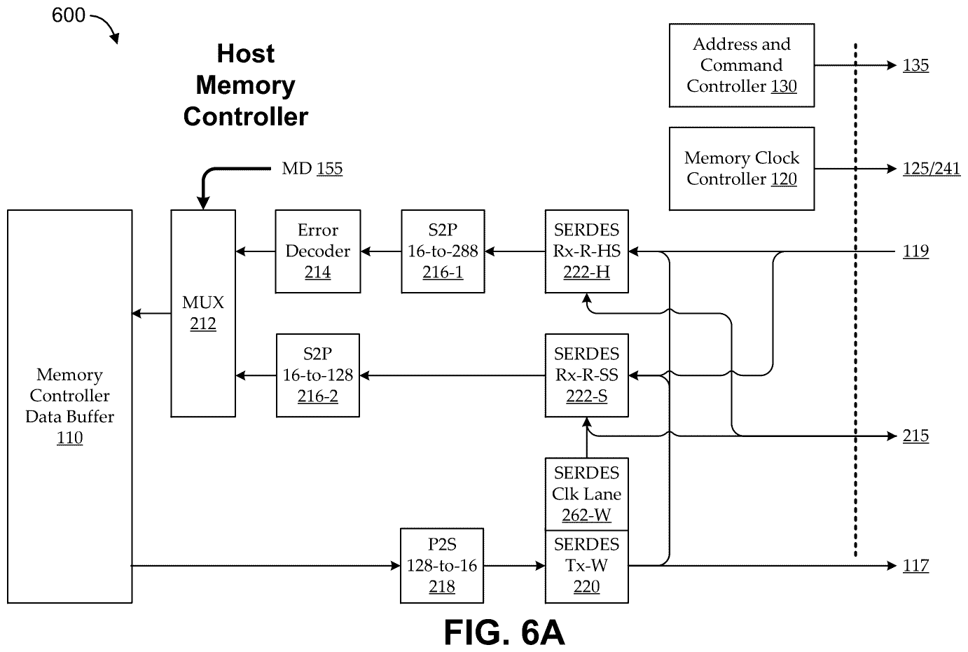

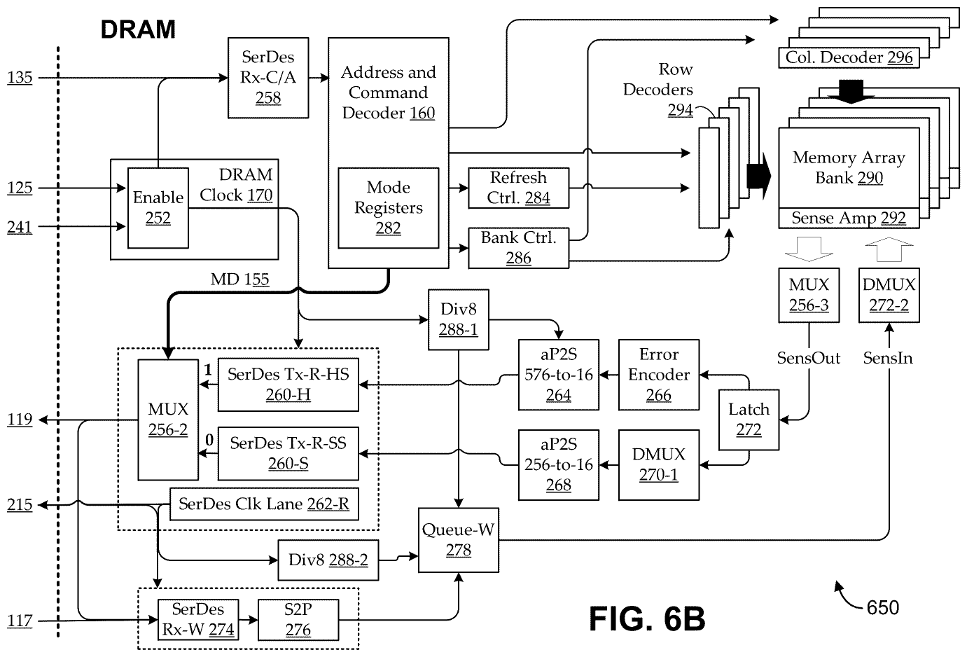

FIGS. 6A and 6B show a host memory controller 600 and a dynamic random-access memory (DRAM) 650, respectively, of an illustrative implementation of a multi-modal DRAM architecture, according to some embodiments described herein. The DRAM architecture of FIGS. 6A and 6B can be an implementation of the DRAM architecture 100 of FIG. 1, such that host memory controller 600 can be an implementation of host memory controller 105, and DRAM 650 can be an implementation of DRAM 150. The architecture illustrated by FIGS. 6A and 6B achieves different read transfer rates using different-order modulation techniques without relying on multiple clock sources.

As illustrated, the memory clock controller 120 generates a single CLK 125 at a particular clock frequency (e.g., at 3200 MHz), along with a corresponding clock enable signal 241. Those signals are received by the DRAM clock 170, which essentially outputs a single clock domain. The address and command controller 130 operates as described above, including generating C/A data 135 to indicate whether to configure the DRAM 650 for the write pipeline 113, SS read pipeline 115-1, or HS read pipeline 115-2. As described above, the address and command decoder 160 in the DRAM 650 receives the C/A data 135 and performs operations, accordingly, including outputting the mode select signal 155.

As illustrated, the write pipeline 113 can be implemented in substantially that same manner as in the architectures of FIG. 1, FIGS. 2A and 2B, or in any other suitable manner. In the SS read pipeline 115-1, data rates and modulation schemes are selected to ensure reliable data transmission with minimal error rates. On the host memory controller 600 side, the memory controller data buffer 110 temporarily stores the read data received from the DRAM 650. The S2P converter 216-2 deserializes the incoming 16-bit serial data streams into 128-bit parallel data suitable for processing by the host system. This converter 216-2 operates at standard speeds appropriate for CPU operations. The serializer/deserializer receiver for standard-speed read data (SerDes Rx-R-SS) 222-S receives the serial read data transmitted from the DRAM 650, using a lower-order modulation scheme (e.g., non-return-to-zero (NRZ) modulation), which provides robust and reliable data transmission at standard speeds. A multiplexer (MUX) 212, controlled by the mode select signal MD 155, selects the standard-speed data path during SS read operations, routing the deserialized data from the S2P converter 216-2 to the memory controller data buffer 110.

The address and command controller 130 processes standard-speed read commands and generates the mode select signal MD 155 to indicate SS read mode. In the DRAM 650, the address and command decoder 160 receives the serialized command and address data from the host memory controller 600 and decodes the standard-speed read command, initiating the read operation on the specified memory addresses. The memory array bank 290 contains the stored data organized into rows and columns, with the row decoders 294 and column decoders 296 selecting the appropriate memory cells based on the address information. The sense amplifiers 292 detect and amplify the small voltage differentials representing the stored data, ensuring accurate retrieval. The data latch 272 temporarily holds the amplified data to stabilize it before serialization, preventing data corruption due to timing variations or electrical noise.

An aP2S 268 converts the 256-bit parallel data into 16-bit serial data streams suitable for transmission, matching the data rate of standard-speed operations. The serializer/deserializer transmitter for standard-speed read data (SerDes Tx-R-SS) 260-S serializes and transmits the read data using NRZ modulation, operating at the standard clock frequency provided by the single clock domain in the DRAM 650. The mode select signal (MD) 155 controls a multiplexer (MUX 256) within the DRAM 650 to select the standard-speed data path, ensuring that the correct operational mode is active for SS read operations.

The data flow in the SS read pipeline 115-1 begins with the host memory controller 600 sending a standard-speed read command and address to the DRAM 650. The address and command decoder 160 in the DRAM decodes the command, activating the appropriate memory cells in the memory array bank 290. The sense amplifiers 292 retrieve the data, which is then latched by the data latch 272. The parallel data is converted into serial data by the aP2S converter 268. The SerDes Tx-R-SS 260-S transmits the serialized data using NRZ modulation over the DQ lines to the host memory controller. The SerDes Rx-R-SS 222-S in the host memory controller receives the serial data and passes it to the S2P converter 216-2, which deserializes the data into parallel form. The MUX 212 routes the deserialized data to the memory controller data buffer 110, making it available for the CPU or other components desiring standard-speed read access.

For the HS read pipeline 115-2, the architecture seeks to optimize read operations for read-intensive (e.g., NPU) workloads. This pipeline achieves increased data throughput by utilizing higher-order modulation techniques without relying on a different clock source. On the host memory controller 600 side, the memory controller data buffer 110 temporarily stores the high-speed read data received from the DRAM 650. The error decoder 214 processes the incoming data to detect and correct errors using forward error correction (FEC) codes, enhancing data integrity and compensating for the higher bit error rates associated with high-speed data transmission. The S2P converter 216-1 deserializes the 16-bit serial data streams into 228-bit parallel data, which includes both data and redundancy bits. This converter 216-1 accommodates the higher data rates and wider data paths required for high-speed operations.

A serializer/deserializer receiver for high-speed read data (SerDes Rx-R-HS) 222-H receives the serial read data transmitted from the DRAM 650, utilizing higher-order modulation schemes, such as pulse amplitude modulation with four levels (PAM4) to effectively increase (e.g., double) the data rate without increasing the clock frequency. The multiplexer 212, controlled by the mode select signal MD 155, selects the high-speed data path during HS read operations, routing the deserialized and error-corrected data to the memory controller data buffer 110. The address and command controller 130 processes high-speed read commands and generates the mode select signal MD 155 to indicate HS read mode.

In the DRAM 650, the address and command decoder 160 decodes the high-speed read command, initiating the read operation on the specified memory addresses. The memory array bank 290's row decoders 294 and column decoders 296 select the appropriate memory cells based on the address information, and the sense amplifiers 292 retrieve the data. The data latch 272 temporarily holds the amplified data to stabilize it before further processing. The error encoder 266 applies FEC codes, such as a 64/8 single error correction double error detection (SECDED) Hamming code, introducing redundancy bits that enable error detection and correction in the host memory controller. The aP2S 264 converts the 576-bit parallel data (including redundancy bits) into 16-bit serial data streams, matching the data rate for high-speed operations. A serializer/deserializer transmitter for high-speed read data (SerDes Tx-R-HS) 260-H serializes and transmits the read data using higher-order modulation schemes, like PAM4. This effectively provides higher data rates at a same clock frequency. The mode select signal MD 155 controls MUX 256 within the DRAM to select the high-speed data path, ensuring that the correct operational mode is active for HS read operations.

The data flow in the HS read pipeline begins with the host memory controller 600 sending a high-speed read command and address to the DRAM 650. The address and command decoder 160 in the DRAM decodes the command, activating the appropriate memory cells in the memory array bank 290. The sense amplifiers 292 retrieve the data, which is then latched by the data latch 272. The error encoder 266 in the DRAM applies FEC codes to the data, adding redundancy bits for error correction. The combined data and redundancy bits form a 576-bit parallel data block, which is serialized by the aP2S converter 264 into 16-bit serial data streams suitable for high-speed transmission. The SerDes Tx-R-HS 260-H transmits the serialized data using higher-order modulation schemes like PAM4 over the DQ lines to the host memory controller. On the host memory controller side, the SerDes Rx-R-HS 222-H receives the serial data and passes it to the S2P converter 216-1, which deserializes the data into a 228-bit parallel form, including both data and redundancy bits. The error decoder 214 processes the data to detect and correct any errors using the FEC codes. The MUX 212 directs the corrected data to the memory controller data buffer 110, making it available for the NPU or other components requiring high-speed read access.

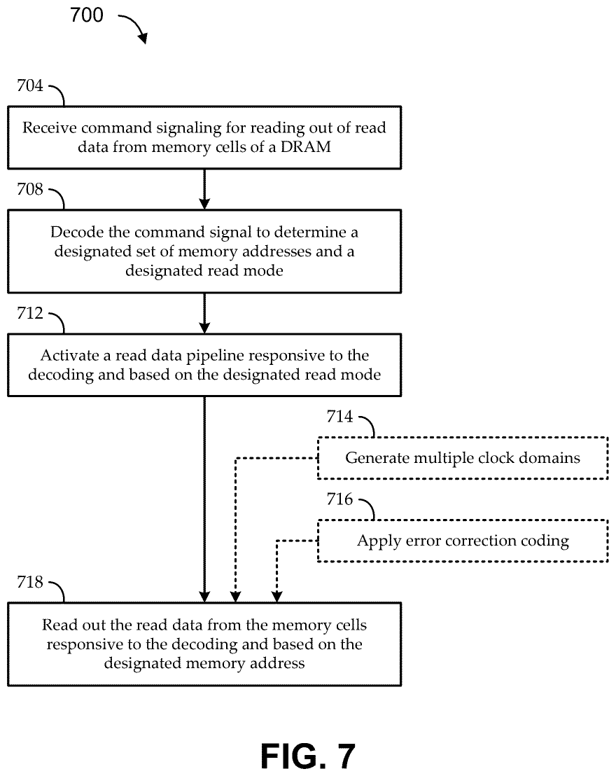

FIG. 7 shows a flow diagram of a method 700 for multi-mode data transfer in a dynamic random-access memory (DRAM) architecture, according to embodiments described herein. Embodiments of the method 700 begin at stage 704 by receiving command signaling for reading out of read data from memory cells of a DRAM. The DRAM receives command and address data (C/A data) from a host memory controller, where the command signaling designates a set of memory addresses corresponding to memory cells in which the read data is stored, and designates a read mode selected from a plurality of read data transfer modes.

As described herein, each read mode is associated with a different read data pipeline and a different data rate, optimizing data transfer for various processing needs. In some embodiments, a first read mode is for operations with symmetrical read and write data rates, and a second read mode is for operations with an asymmetric read data rate higher than the write data rate. For example, the first read mode is for lower-transfer-speed (LTS) operations, such as for central processing unit (CPU) operations, and the second read mode is for higher-transfer-speed (HTS) operations, such as for neural processing unit (NPU) operations.

In stage 708, embodiments can decode the command signal to determine the designated set of memory addresses and the designated read mode. An address and command decoder within the DRAM interprets the received C/A data to identify the specific memory cells to access and determines the read mode specified by the command signaling. This decoding process enables the DRAM to configure subsequent operations based on the read mode, facilitating dynamic switching between different data transfer modes on a per-command (e.g., per-burst) basis.

In some embodiments, the set of memory addresses and the designated read mode can be determined without explicitly decoding a command signal (i.e., the method 700 can be implemented without performing stage 708). For example, the set of memory addresses and/or the read mode can be provided directly by the host memory controller in preprocessed form, allowing the DRAM to bypass the decoding step. Alternatively, the DRAM may include pre-configured address mappings or lookup tables that associate specific memory addresses and read modes with generic commands or triggers. In another embodiment, the DRAM can infer the set of memory addresses and the read mode through pattern recognition, heuristic algorithms, or other contextual information derived from incoming data or signals. In yet another embodiment, the host memory controller may fully determine the memory addresses and read modes prior to transmitting them to the DRAM, enabling the DRAM to execute the instructions without relying on decoding of a command signal.

In stage 712, embodiments can activate a read data pipeline (e.g., responsive to the decoding) and based on the designated read mode. The control logic in the DRAM selects the appropriate read data pipeline corresponding to the designated read mode. This activation may involve configuring specific pathways, buffers, and modulation schemes to handle the read data at the designated data rate. For example, the DRAM may choose between a standard-speed read pipeline optimized for symmetrical read and write data rates (e.g., for CPU workloads), and a high-speed read pipeline optimized for higher read data rates (e.g., for NPU workloads).

In some embodiments, in stage 714, embodiments can generate multiple clock domains. The DRAM architecture includes clock generation circuitry that produces different clock domains to support varying data rates required by the different read modes. A standard-speed clock domain may be generated for standard read and write operations, while a high-speed clock domain is generated for high-speed read operations. The high-speed clock domain can operate at a frequency that is an integer multiple of the standard-speed clock domain, allowing the DRAM to support higher data transfer rates without compromising synchronization and timing accuracy.

In some embodiments, in stage 716, embodiments can apply error correction coding. For at least one of the read data transfer modes, particularly the high-speed mode, the DRAM applies error correction coding (ECC) to the read data before transmission. This involves encoding the read data using techniques such as Hamming codes to add redundancy bits, enabling detection and correction of errors that may occur during high-speed data transfer. Applying ECC is crucial for maintaining data integrity, especially when using higher data rates that may increase the bit error rate due to factors like reduced signal voltage swing or increased noise.

In stage 718, embodiments can read out the read data from the memory cells responsive to the decoding and based on the designated memory addresses. The DRAM accesses the specified memory cells in its memory array and retrieves the stored data. The read data is then output from the DRAM to the host memory controller via the activated read data pipeline at the data rate associated with the designated read mode. This process may involve transmitting the read data over shared data lines, utilizing the selected modulation scheme and clock domain to ensure efficient and reliable data transfer aligned with the processing requirements of the host system.

In some embodiments, the command signaling received at stage 704 is first command signaling received for first read data. For example, the first command signaling is received in a first timeframe, designates a first set of memory addresses, and designates a first read mode associated with a first read data pipeline and a first data rate. At some subsequent time, second command signaling is received for second read data (i.e., in a subsequent iteration of stage 704). For example, the second command signaling designates a second set of memory addresses and a second read mode associated with a second read data pipeline and a second data rate. In such embodiments, in a corresponding iteration of one or more of stages 712-718 during the first timeframe, the first read data is output from the DRAM to the host memory controller via the first read data pipeline at the first data rate; and in a corresponding iteration of one or more of stages 712-718 during the second timeframe, the second read data is output from the DRAM to the host memory controller via the second read data pipeline at the second data rate.

It will be understood that, when an element or component is referred to herein as “connected to” or “coupled to” another element or component, it can be connected or coupled to the other element or component, or intervening elements or components may also be present. In contrast, when an element or component is referred to as being “directly connected to,” or “directly coupled to” another element or component, there are no intervening elements or components present between them. It will be understood that, although the terms “first,” “second,” “third,” etc. may be used herein to describe various elements, components, these elements, components, regions, should not be limited by these terms. These terms are only used to distinguish one element, component, from another element, component. Thus, a first element, component, discussed below could be termed a second element, component, without departing from the teachings of the present invention. As used herein, the terms “logic low,” “low state,” “low level,” “logic low level,” “low,” or “0” are used interchangeably. The terms “logic high,” “high state,” “high level,” “logic high level,” “high,” or “1” are used interchangeably.

As used herein, the terms “a”, “an” and “the” may include singular and plural references. It will be further understood that the terms “comprising”, “including”, having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components. Furthermore, as used herein, the words “and/or” may refer to and encompass any possible combinations of one or more of the associated listed items.

While the present invention is described herein with reference to illustrative embodiments, this description is not intended to be construed in a limiting sense. Rather, the purpose of the illustrative embodiments is to make the spirit of the present invention be better understood by those skilled in the art. In order not to obscure the scope of the invention, many details of well-known processes and manufacturing techniques are omitted. Various modifications of the illustrative embodiments, as well as other embodiments, will be apparent to those of skill in the art upon reference to the description. It is therefore intended that the appended claims encompass any such modifications.

Furthermore, some of the features of the preferred embodiments of the present invention could be used to advantage without the corresponding use of other features. As such, the foregoing description should be considered as merely illustrative of the principles of the invention, and not in limitation thereof. Those of skill in the art will appreciate variations of the above-described embodiments that fall within the scope of the invention. As a result, the invention is not limited to the specific embodiments and illustrations discussed above, but by the following claims and their equivalents.

What is claimed is:

1. A method for multi-mode data transfer in a dynamic random-access memory (DRAM) architecture, the method comprising:
receiving, at a DRAM from a host memory controller, command signaling for reading out of read data from memory cells of the DRAM;
determining a designated set of memory addresses and a designated read mode associated with the command signaling,
wherein the designated set of memory addresses corresponds to memory cells in which the read data is stored, the designated read mode is one of a plurality of read data transfer modes, and each of the plurality of read data transfer modes is associated with a different respective one of a plurality of read data pipeline and a different respective data rate;
activating the respective read data pipeline based on the designated read mode; and
reading out the read data from the memory cells based on the designated memory address, thereby outputting the read data from the DRAM to the host memory controller via the respective read data pipeline at the respective data rate.

2. The method of claim 1, wherein the designated set of memory addresses and/or the designated read mode is determined by decoding the command signal.

3. The method of claim 1, wherein the command signaling is first command signaling received for first read data, wherein the first command signaling is received at in first timeframe, designates a first set of memory addresses, and designates a first read mode associated with a first read data pipeline and a first data rate, and further comprising:
receiving second command signaling for second read data, wherein the second command signaling is received in a second timeframe subsequent to the first timeframe, designates a second set of memory addresses, and designates a second read mode associated with a second read data pipeline and a second data rate,
such that the first read data is output from the DRAM to the host memory controller via the first read data pipeline at the first data rate in the first timeframe, and the second read data is output from the DRAM to the host memory controller via the second read data pipeline at the second data rate in the second timeframe.

4. The method of claim 1, wherein the plurality of read data transfer modes includes:
a first read mode for operations with symmetrical read and write data rates; and
a second read mode for operations with an asymmetric read data rate higher than the write data rate.

5. The method of claim 1, wherein activating the respective read data pipeline comprises selecting one of a plurality of clock domains based on the designated read mode.

6. The method of claim 4, further comprising:
receiving a clock signal by the DRAM from the host memory controller;
generating a first clock domain of the plurality of clock domains from the clock signal; and
generating a second clock domain of the plurality of clock domains by multiplying or dividing the first clock domain.

7. The method of claim 1, wherein each of the different respective data rates is achieved using a different respective modulation scheme in the different respective read data pipeline.

8. The method of claim 1, further comprising:
applying error correction coding to the read data in at least one of the plurality of read data transfer modes.

9. The method of claim 8, wherein applying error correction coding comprises encoding the read data within the DRAM for decoding within the host memory controller.

10. The method of claim 1, further comprising:
applying error correction coding to the read data in only one of the plurality of read data transfer modes.

11. The method of claim 1, wherein:
the respective read data pipelines share data lines coupled between the DRAM and host memory controller; and
outputting the read data comprises transmitting the read data over the shared data lines.

12. A dynamic random-access memory (DRAM) system with multiple data transfer modes, the DRAM system comprising:
a memory array comprising memory cells configured to store data;
an interface configured to receive, from a host memory controller, command and address data (C/A data) for reading out read data from the memory cells;
logic configured to determine a designated set of memory addresses and a designated read mode,
wherein the designated set of memory addresses corresponds to memory cells in which the read data is stored, the designated read mode is one of a plurality of read data transfer modes, and each of the plurality of read data transfer modes is associated with a different respective one of a plurality of read data pipeline and a different respective data rate;
control logic configured to activate the respective read data pipeline based on the designated read mode; and
the plurality of read data pipelines, each configured to read out the read data from the memory cells responsive to the decoding and based on the designated memory addresses, thereby outputting the read data from the DRAM to the host memory controller at the respective data rate based on the designated read mode.

13. The DRAM system of claim 12, wherein:
the C/A data further designates the set of memory addresses corresponding to memory cells in which the read data is stored and/or designates the read mode of the plurality of read data transfer modes; and
the logic configured to determine the designated set of memory addresses and the designated read mode comprises an address and command decoder configured to decode the C/A data to determine the designated set of memory addresses and/or the designated read mode.

14. The DRAM system of claim 12, wherein:
the interface is configured to receive first command and address data for first read data, wherein the first command and address data is received in a first timeframe, designates a first set of memory addresses, and designates a first read mode associated with a first read data pipeline and a first data rate; and
the interface is further configured to receive second command and address data for second read data, wherein the second command and address data is received in a second timeframe subsequent to the first timeframe, designates a second set of memory addresses, and designates a second read mode associated with a second read data pipeline and a second data rate,
such that the read circuitry outputs the first read data to the host memory controller via the first read data pipeline at the first data rate in the first timeframe, and outputs the second read data to the host memory controller via the second read data pipeline at the second data rate in the second timeframe.

15. The DRAM system of claim 12, wherein the plurality of read data transfer modes includes:
a first read mode for operations with symmetrical read and write data transfer rates; and
a second read mode for operations with an asymmetric read data rate higher than the write data rate.

16. The DRAM system of claim 12, wherein activating the respective read data pipeline comprises selecting one of a plurality of clock domains based on the designated read mode.

17. The DRAM system of claim 16, further comprising:
a DRAM clock having a multiplier, wherein:
the interface is further configured to receive a first clock signal from the host memory controller;
the multiplier is configured to generate a second clock signal as an integer multiple of the first clock signal; and
the DRAM clock is configured to output the first clock signal as a first clock domain of the plurality of clock domains and to output the second clock signal as a second clock domain of the plurality of clock domains.

18. The DRAM system of claim 16, further comprising:
a DRAM clock having a phase-locked loop (PLL), wherein:
the interface is further configured to receive a first clock signal from the host memory controller;
the PLL is configured to generate a second clock signal having a frequency that is M/N times that of the first clock signal, wherein M is a post-divider of the PLL, N is an input divider of the PLL, and M and N are integers; and
the DRAM clock is configured to output the first clock signal as a first clock domain of the plurality of clock domains and to output the second clock signal as a second clock domain of the plurality of clock domains.

19. The DRAM system of claim 12, wherein each of the different respective data rates is achieved using a different respective modulation scheme in the different respective read data pipelines.

20. The DRAM system of claim 12, further comprising:
error correction coding circuitry configured to apply error correction coding to the read data in fewer than all of the plurality of read data transfer modes.
